(19) United States
(12) Patent Application Publication
(10) Pub. No.: US 2026/0328818 A1
(43) Pub. Date: Oct. 22, 2026

(54) APPARATUS FOR MEASURING THE INTENSITY OF A CURRENT FLOW ALONG AN ELONGATED ELECTRICAL CONDUCTOR, WITH ELASTIC RETAINING STRUCTURE

(71) Applicant: WAGO Verwaltungsgesellschaft mbH, Minden (DE)

(72) Inventors: Tristan NENTWIG, Bueckeburg (DE); Henning KELCH, Minden (DE)

(73) Assignee: WAGO Verwaltungsgesellschaft mbH, Minden (DE)

(21) Appl. No.: 19/649,722

(22) Filed: Apr. 16, 2026

(30) Foreign Application Priority Data
Apr. 17, 2025 (DE) 20 2025 102 153.6

(51) Int. Cl. G01R 19/00; G01R 15/14; G01R 29/08

(52) U.S. Cl. CPC G01R 19/0092; G01R 15/148; G01R 29/0878

(57) ABSTRACT

An apparatus to measure an intensity of a current flow along an elongated electrical conductor is provided. The apparatus comprises a magnetically permeable structure, a first magnetic field sensor, a second magnetic field sensor, and an elastic retaining structure arranged in a space partially enclosed by the magnetically permeable structure. The elastic retaining structure has a receiving area that extends substantially parallel to a line through the magnetic field sensors. The elastic retaining structure enables the elongated electrical conductor to be inserted transversely to a longitudinal axis of the elongated electrical conductor into the receiving area through reversible deformation of the elastic retaining structure.

This nonprovisional application claims priority under 35 U.S.C. § 119(a) to German Patent Application No. 20 2025 102 153.6, which was filed in Germany on Apr. 17, 2025, and which is herein incorporated by reference.

### BACKGROUND OF THE INVENTION

### Field of the Invention

The present disclosure relates to an apparatus for measuring the intensity of a current flow along an elongated electrical conductor using magnetic field sensors. In particular, the present disclosure relates to an apparatus for measuring the intensity of a current flow along an elongated electrical conductor, wherein the apparatus comprises an elastic retaining structure which is to receive and accommodate the electrical conductor.

### Description of the Background Art

When measuring the intensity of a current flow along an elongated electrical conductor using magnetic field sensors, the accuracy of the measurement may depend on the position of the electrical conductor relative to the magnetic field sensors.

### SUMMARY OF THE INVENTION

It is therefore an object of the present invention to provide an apparatus that can comprise a magnetically permeable structure, a first magnetic field sensor, a second magnetic field sensor and an elastic retaining structure. The elastic retaining structure may be arranged in a space which may be partially enclosed by the magnetically permeable structure.

The elastic retaining structure may comprise a receiving area which may extend parallel to a line through the magnetic field sensors. The elastic retaining structure may allow for the insertion of the elongated electrical conductor transversely to a longitudinal axis of the elongated electrical conductor into the receiving area by way of a (simultaneous) reversible deformation of the elastic retaining structure.

The elasticity of the retaining structure may allow for arranging elongated electrical conductors of different cross-sections in a specific position and orientation relative to the magnetic field sensors in the space which may be partially enclosed by the magnetically permeable structure. In particular, the elastic retaining structure may facilitate arranging elongated electrical conductors of different cross-sections centrally in a designated measuring area within the space which may be partially enclosed by the magnetically permeable structure.

For example, a cross-section of the elastic retaining structure may be mirror-symmetric to a plane that divides the elongated electrical conductor (and preferably also the magnetically permeable structure) into two halves, if the elongated magnetic conductor is arranged centrally in the measuring area, so that the forces acting on the elongated electrical conductor due to the elasticity of the retaining structure may cancel each other out (if the elongated magnetic conductor is arranged centrally in the measuring area).

Furthermore, any calibration or positional compensation that may be necessary when measuring the intensity of the current flow may be reduced by one degree of freedom if, based on the design of the apparatus, it can be assumed that the elongated electrical conductor is arranged centrally in the measuring area. For example, a processing unit downstream of the magnetic field sensors may process sensor signals under the assumption that the elongated electrical conductor is arranged centrally in the measuring area.

In this regard, the term “magnetically permeable structure”, may refer to a structure made of a magnetically permeable material, e.g. a structure made of a ferromagnetic material such as a mu-metal. Furthermore, a magnetically permeable structure, “which partially surrounds a space in which the holding structure is arranged,” may refer to a magnetically permeable structure which comprises a concave region in which the elastic retaining structure is arranged, wherein the elongated electrical conductor extends through the concave region when the elongated electrical conductor is inserted into the elastic retaining structure.

Furthermore, the term "magnetic field sensor" may refer to a sensor that provides measured values on a magnetic flux density of a magnetic field. The magnetic field sensors may be configured to measure a magnetic field strength perpendicular to the surface of the magnetically permeable structure facing the elongated electrical conductor.

Moreover, the cross-section of the magnetically permeable structure (at least in an area around the elongated electrical conductor) may exhibit an axis of mirror symmetry. In this regard, a magnetically permeable structure “whose cross-section exhibits an axis of mirror symmetry at least in an area around the electrical conductor”, may refer to a magnetically permeable structure the cross-section of which has a section through which the electrical conductor extends and which is mirror-symmetric to the axis of mirror symmetry. The section may be rectangular, square, oval, or circular. The electrical conductor may extend through a center of the section. The area of the cross-section around the elongated electrical conductor which exhibits the axis of mirror symmetry may comprise more than 50%, more than 75% or more than 90% of a cross-sectional area of the magnetically permeable structure.

The axis of mirror symmetry may (essentially) pass through a center of the magnetically permeable structure. A longitudinal axis of a section of the elongated electrical conductor surrounded by the permeable structure may be perpendicular to the axis of mirror symmetry. Magnetic field sensors may be offset from one another parallel to the axis of mirror symmetry.

The measured values of the magnetic field sensors may be used to compensate for an offset of the elongated electrical conductor parallel to the axis of mirror symmetry, which may result from, for example, elongated electrical conductors that have different cross-sections. For example, as part of a calibration procedure, an elongated electrical conductor may be placed at different positions in the apparatus and the measured values of the magnetic field sensors may be recorded and/or processed, so that by comparing the measured values recorded during operation with the measured values generated as part of the calibration procedure (or values derived therefrom), the position of the elongated electrical conductor may be determined or a measurement curve suitable for the actual position of the elongated electrical conductor may be determined.

Furthermore, the term "elastic retaining structure," may refer to a structure which comprises an insertion opening that is smaller transversely to the insertion direction than the diameter or width of the smallest elongated electrical conductor to be inserted and that is larger in the insertion direction than the diameter or height of the largest elongated electrical conductor to be inserted, such that a fully inserted elongated electrical conductor is at least partially surrounded by the elastic retaining structure in a direction opposite to the insertion direction. Withdrawing the elongated electrical conductor from the elastic retaining structure may require compressing a part of the elastic retaining structure, which may facilitate or prevent the withdrawal of the elongated electrical conductor and contribute to or cause the elongated electrical conductor to be fixed in the apparatus or the apparatus being fixed to the elongated electrical conductor.

The elastic retaining structure may comprise springs extending from a base. The free ends of the springs may protrude into the receiving area. The free ends of the springs may point inwards and in the direction of insertion, in a barbed manner.

The elastic retaining structure may comprise one, two, three or four spring combs.

The elastic retaining structure may comprise two spring combs which may be arranged in a mirror-symmetrical manner with respect to an axis of mirror symmetry running parallel to the insertion direction.

The apparatus may further comprise a releasable bracket which may block a relative movement of the two spring combs, wherein the movement would otherwise facilitate withdrawing the elongated electrical conductor from the retaining structure.

The magnetically permeable structure may encircle the elongated electrical conductor only partially.

The magnetically permeable structure may have a U-shaped cross-section.

The releasable bracket may encircle the electrical conductor only partially.

The releasable bracket may encircle the magnetically permeable structure only partially.

The releasable bracket may have a U-shaped cross-section.

The magnetically permeable structure and the releasable bracket may comprise a concave region into which the elongated electrical conductor can be inserted transversely to the longitudinal axis of the elongated electrical conductor if the releasable bracket at least partially encircles the magnetically permeable structure.

The elastic retaining structure may comprise a tubular element which may delimit a cavity that extends parallel to the insertion direction transversely to the insertion direction.

The tubular element may be a bellows.

The elastic retaining structure may comprise two first wall-shaped elements and two second wall-shaped elements, wherein the first and second wall-shaped elements are arranged in a mirror-symmetric manner with respect to an axis of mirror symmetry running parallel to the insertion direction.

The wall-shaped elements may comprise recesses.

The magnetically permeable structure may be provided with a housing. The cross-section of the housing may have a V-shaped recess, and the elongated electrical conductor may extend through the V-shaped recess.

The first magnetic field sensor and the second magnetic field sensor may be arranged in a mirror-symmetrical manner with respect to the axis of mirror symmetry.

The apparatus may comprise a third magnetic field sensor. The first magnetic field sensor and the second magnetic field sensor may be arranged in a mirror-symmetrical manner with respect to the axis of mirror symmetry. The third magnetic field sensor may be offset relative to the first magnetic field sensor parallel to the axis of mirror symmetry.

The apparatus may comprise a fourth magnetic field sensor. The third magnetic field sensor and the fourth magnetic field sensor may be arranged in a mirror-symmetrical manner with respect to the axis of mirror symmetry. The fourth magnetic field sensor may be offset relative to the second magnetic field sensor parallel to the axis of mirror symmetry.

The apparatus may comprise a fifth magnetic field sensor. The fifth magnetic field sensor may be offset relative to the first and third magnetic field sensors parallel to the axis of mirror symmetry.

The apparatus may comprise a sixth magnetic field sensor. The fifth magnetic field sensor and the sixth magnetic field sensor may be arranged in a mirror-symmetrical manner with respect to the axis of mirror symmetry. The sixth magnetic field sensor may be offset relative to the second and fourth magnetic field sensor parallel to the axis of mirror symmetry.

By using the measured values of the pairs, the influence of interfering fields on the detection of the offset of the elongated electrical conductor parallel to the mirror symmetry axis may be reduced.

The apparatus may comprise an evaluation unit (e.g., a processor or a circuit) which may processes the measured values of the magnetic field sensors and, based on the magnetic field sensors being offset parallel to the mirror symmetry axis, determine a correction factor (which correlates to the distance of the center of the elongated electrical conductor from a base of the magnetically permeable structure). The evaluation unit may apply the correction factor to the measured values to determine the intensity of the current flow through the elongated electrical conductor.

Furthermore, it is understood that the features described in connection with the apparatus may equally be features of a method for measuring the intensity of the current flow through the elongated electrical conductor and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1a and 1b show a schematic representation of an apparatus according to an example;

FIGS. 2a and 2b show a schematic representation of an apparatus according to an example;

FIGS. 3a and 3b show a schematic representation of an apparatus according an example;

FIGS. 4a and 4b show a schematic representation of an apparatus according to an example;

FIGS. 5a and 5b show a schematic representation of an apparatus according to an example;

FIG. 6 shows a schematic representation of a first modification of the examples; and

FIG. 7 shows a schematic representation of a second modification of the examples.

### DETAILED DESCRIPTION

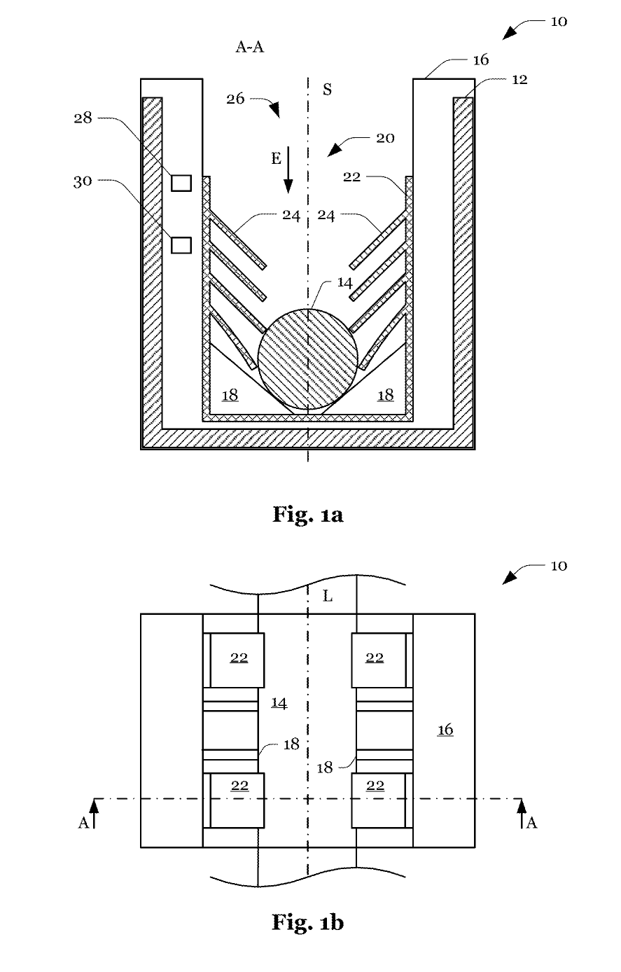

FIG. 1a shows a cross-sectional view of an apparatus 10 according to an example, and FIG. 1b shows a top view of the apparatus 10 shown in FIG. 1a. The apparatus 10 comprises a magnetically permeable structure 12. The magnetically permeable structure 12 surrounds an elongated electrical conductor 14 which has a circular cross-section. Notably, the invention is not limited to elongated electrical conductors 14 with circular cross-sections. For example, the elongated electrical conductor 14 may have a triangular, square, pentagonal, hexagonal, or polygonal cross-section.

The magnetically permeable structure 12 has a U-shaped cross-section. The U-shaped cross-section has an axis S of mirror symmetry, which is perpendicular to the longitudinal axis L of the elongated electrical conductor 14. The magnetically permeable structure 12 is further provided with a housing 16. The cross-section of the housing 16 has a V-shaped recess, with the elongated electrical conductor 14 resting against the wall elements 18 that define the recess. The housing 16 is further provided with an elastic retaining structure 20. The elastic retaining structure 20 comprises a U-shaped base 22. Springs 24 extend from both legs of the U-shaped base 22, with their free ends protruding into the receiving area 26.

The free ends of the springs 24 (of the spring comb formed from the base 22 and the springs 24) point inwards and in the insertion direction E, in a barbed manner, so that a movement of the elongated electrical conductor 14 (which has been inserted into the receiving area 26) relative to the apparatus 10 opposite to the insertion direction E results in strain which prevents the movement. If, on the other hand, the elongated electrical conductor 14 is inserted into the receiving area 26 transversely to the longitudinal axis L of the elongated electrical conductor 14, the free ends of the springs 24 are bent outwards and return to their initial position after the elongated electrical conductor 14 has been moved past them. The elongated electrical conductor 14 is aligned centrally relative to the legs of the magnetically permeable structure 12 by the forces exerted on the elongated electrical conductor 14 by the bent springs 24.

The apparatus 10 further comprises two magnetic field sensors 28 and 30, which are offset from each other parallel to the axis S of mirror symmetry. The field strength measured in the horizontal direction by the magnetic field sensors 28 and 30 depends on the diameter of the elongated electrical conductor 14. This allows determining the offset of the center of the elongated electrical conductor 14 along the mirror symmetry axis S in relation to the offset on which the nearest available calibration curve is based. The values of the calibration curve may then be used to determine the intensity of the current flow through the elongated electrical conductor 14 using a correction factor.

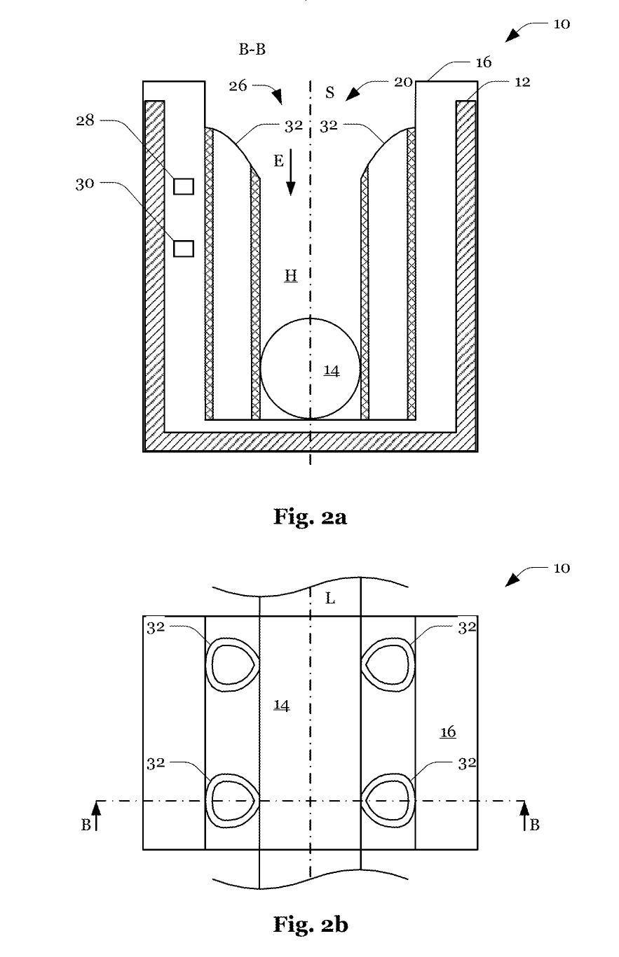

As shown in FIGS. 2a and 2b, the elastic retaining structure 20 may also be formed by tubular elements 32 instead of spring combs. The tubular elements 32 may delimit a cavity H (which extends parallel to the insertion direction E) transversely to the insertion direction E. The tubular elements 32 may, for example, be (commercially available) hollow seals which may be locally deformed when the elongated electrical conductor 14 is inserted and thereby fix the elongated electrical conductor 14 centrally in the measuring area of the magnetic field sensors 28 and 30.

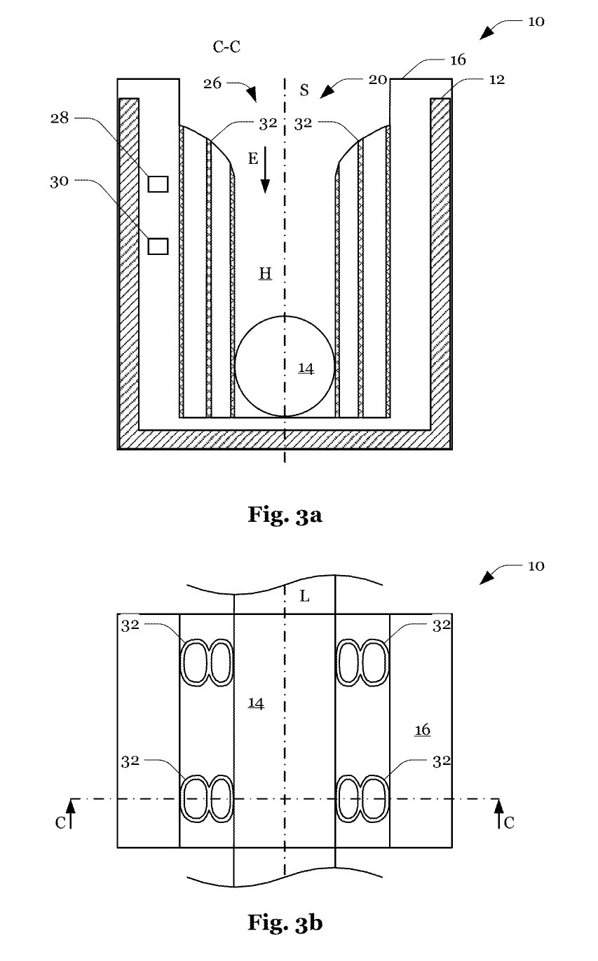

As shown in FIGS. 3a and 3b, the tubular elements 32 may be bellows.

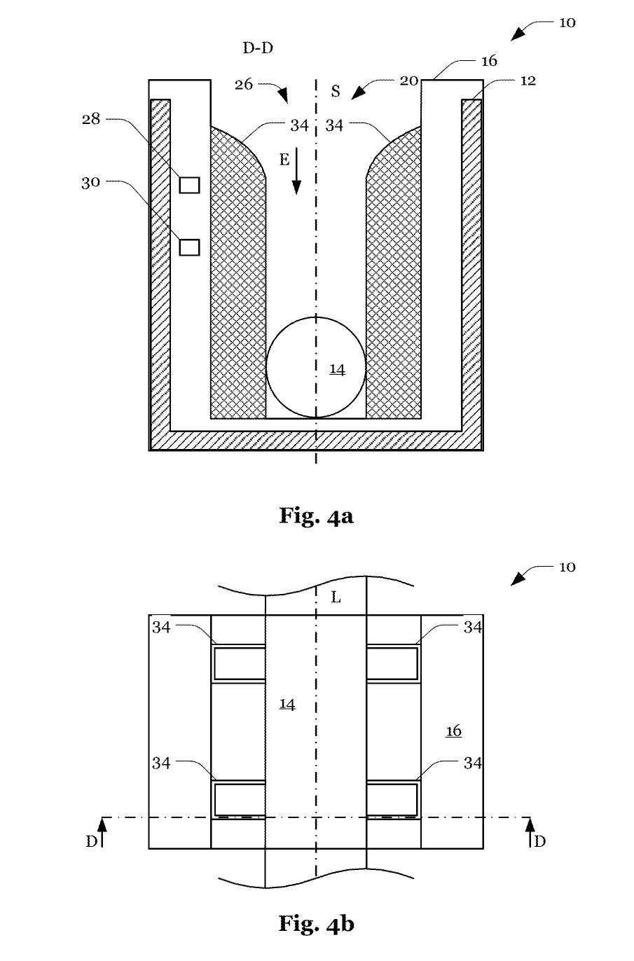

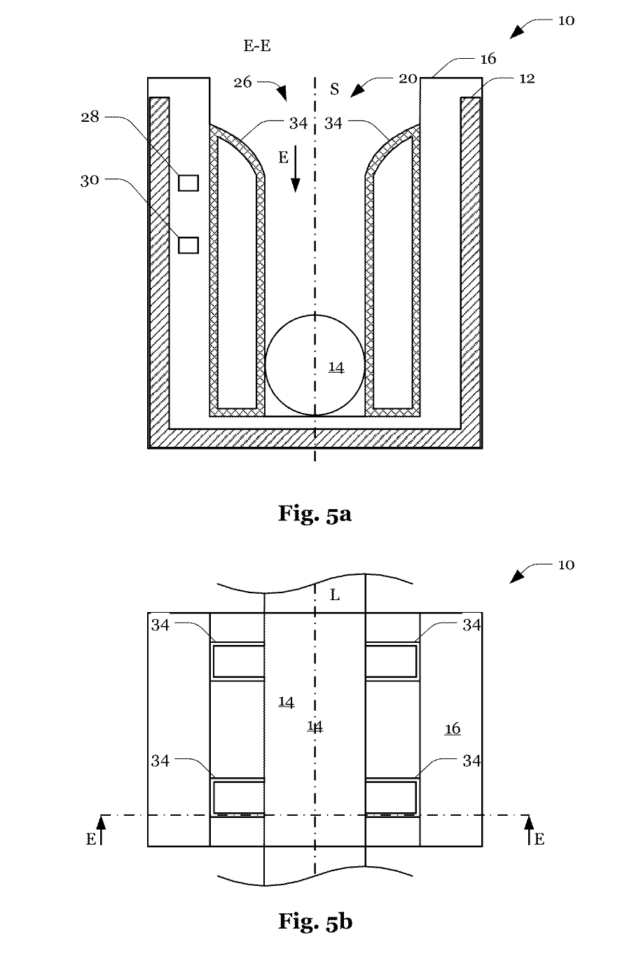

As shown in FIGS. 4a and 4b, the elastic retaining structure 20 may have wall-shaped elements 34 which are arranged in a mirror-symmetric manner with respect to the axis S of symmetry which runs parallel to the insertion direction E. As shown in FIGS. 5a and 5b, the wall-shaped elements 34 may have cut-outs. The cut-outs may reduce the resistance to the insertion of the elongated electrical conductor 14 (due to the local deformation that travels along with the elongated electrical conductor 14 in the insertion direction E). The cut-outs may possibly also reduce the risk of the wall-shaped elements 34 folding away in the longitudinal direction L.

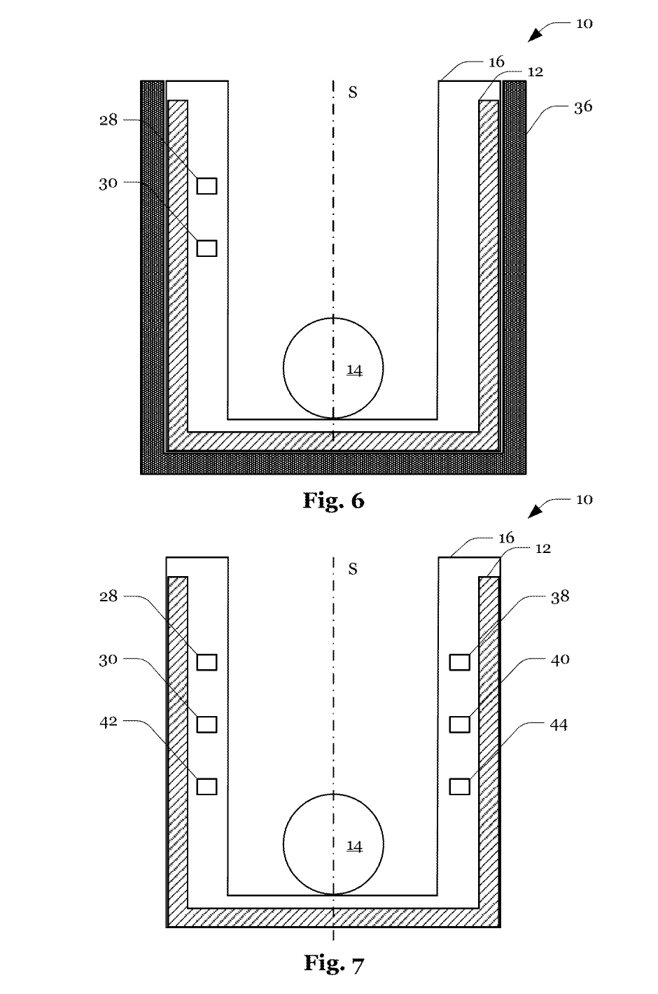

FIG. 6 shows a U-shaped detachable bracket 36, which is pushed onto the apparatus 10 and supports the free ends of the apparatus 10 and thus protects them from being bent outwards, thereby reinforcing the fixation of the elongated electrical conductor 14 in the apparatus 10 or the fixation of the apparatus 10 on the elongated electrical conductor 14. For example, the releasable bracket 36 in the apparatus 10 shown in FIGS. 1a and 1b may block a relative movement of the two spring combs, which would otherwise facilitate withdrawing the elongated electrical conductor 14 from the retaining structure.

As shown in FIG. 7, the apparatus 10 may be provided with further magnetic field sensors 38, 40, 42 and 44, forming pairs of magnetic field sensors 28 and 38, 30 and 40 or 42 and 44 offset from each other parallel to the axis of mirror symmetry, with the magnetic field sensors 28 and 38, 30 and 40 or 42 and 44 of the pairs being arranged in a mirror-symmetric manner with respect to the axis S of mirror symmetry. By using the measured values of the magnetic field sensor pairs, the influence of interfering fields on the detection of the offset of the electrical conductor 12 parallel to the axis S of mirror symmetry may be reduced.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An apparatus to measure an intensity of a current flow along an elongated electrical conductor, the apparatus comprising:
a magnetically permeable structure;
a first magnetic field sensor;
a second magnetic field sensor; and
an elastic retaining structure arranged in a space partially enclosed by the magnetically permeable structure,
wherein the elastic retaining structure has a receiving area that extends substantially parallel to a line through the magnetic field sensors, and
wherein the elastic retaining structure enables the elongated electrical conductor to be inserted transversely to a longitudinal axis of the elongated electrical conductor into the receiving area through reversible deformation of the elastic retaining structure.

2. The apparatus of claim 1, wherein the elastic retaining structure comprises at least one spring extending from a base, a free end of the at least one spring protruding into the receiving area.

3. The apparatus of claim 2, wherein the elastic retaining structure comprises one, two, three or four spring combs.

4. The apparatus of claim 2, wherein the elastic retaining structure comprises two spring combs which are arranged in a mirror-symmetric manner with respect to an axis of mirror symmetry running parallel to an insertion direction.

5. The apparatus of claim 4, further comprising a releasable bracket that blocks a relative movement of the two spring combs, that would otherwise facilitate withdrawing the elongated electrical conductor from the elastic retaining structure.

6. The apparatus of claim 1, wherein the elastic retaining structure comprises a tubular element that delimits a cavity that extends parallel to the insertion direction, transversely to the insertion direction.

7. The apparatus of claim 6, wherein the tubular element is a bellows.

8. The apparatus of claim 1, wherein the elastic retaining structure comprises two first wall-shaped elements and two second wall-shaped elements, wherein the first and second wall-shaped elements are arranged in a mirror-symmetric manner with respect to an axis of mirror symmetry running parallel to the insertion direction.

9. The apparatus of claim 8, wherein the wall-shaped elements comprise recesses.

10. The apparatus of claim 1, wherein the magnetically permeable structure has a U-shaped cross-section.

11. The apparatus of claim 1, wherein the magnetically permeable structure is provided with a housing having a cross-section with a V-shaped recess, and the elongated electrical conductor extends through the V-shaped recess.

12. The apparatus of claim 1, wherein the magnetic field sensors are configured to measure a magnetic field strength perpendicular to a surface of the magnetically permeable structure that faces the elongated electrical conductor.

13. The apparatus of claim 1, wherein the cross-section of the magnetically permeable structure has an axis of mirror symmetry or the cross-section of the magnetically permeable structure has an axis of mirror symmetry at least in an area around the elongated electrical conductor, wherein the magnetic field sensors are offset from each other parallel to the axis of mirror symmetry or arranged mirror-symmetrically to the axis of mirror symmetry, and wherein a longitudinal axis of a section of the elongated electrical conductor surrounded by the permeable structure is substantially perpendicular to the axis of mirror symmetry.

14. The apparatus of claim 13, wherein the area of the cross-section around the elongated electrical conductor that has an axis of mirror symmetry comprises more than 50%, more than 75% or more than 90% of a cross-sectional area of the magnetically permeable structure.
